(19) United States
(12) Patent Application Publication
(10) Pub. No.: US 2003/0090394 A1
(43) Pub. Date: May 15, 2003

(54) Combination keyboard and mouse

(76) Inventor: Ari Zagnoev, Leederville, WA (US)

Correspondence Address: Welsh & Katz, Ltd., Gerald T. Shekleton, 22nd Floor, 120 South Riverside Plaza, Chicago, IL, 60606, US

(21) Appl. No.: 10/001,115

(22) Filed: Nov. 15, 2001

(51) Int. Cl. H03M 11/00; H03K 17/94; G09G 5/08

(52) U.S. Cl. 341/22; 341/20; 345/163; 345/167

(57) ABSTRACT

A combination keyboard and mouse particularly suitable for electronic equipment (e.g. computer) which has at least two parts encompassing a keyboard, and having at least one movable keyboard part arranged on a support surface adapted to be gripped by one hand of a user to be moved on a support surface as a mobile keyboard part to generate pointing movement commands to cause movement of a pointing member on the computer. Specifically, data input keys on the movable keyboard are arranged in a generally QWERTY keyboard layout, wherein at least one data input key is located between the T and the Y keys.

### FIELD OF INVENTION

The present invention relates to keyboards for electronic equipment (e.g. computers).

### BACKGROUND TO INVENTION

Pointing arrangements for desk top computers and other electronic equipment generally make use of the conventional mouse device. The mouse device includes a moveable unit typically jointed by way of a cable to the electronic equipment (e.g. computer), the moveable unit being adapted to be moved on a surface, e.g. a desk. Invariably it is inconvenient to move one's hand to and from the keyboard and the mouse unit.

Current pointing arrangements, that are integrated with keyboards, such as track balls, touchpads and pointing sticks, do not match the dexterity of the conventional mouse and are often not used but are substituted for by a conventional mouse unit coupled to the computer, again resulting in the additional desk space required. Moreover, current point stick integrated keyboard and pointing systems are prone to muscle tremors and other problems, while the touchpad integrated keyboards are inaccurate.

To overcome the problem of moving ones hand between the keyboard and mouse, Zagnoev, U.S. Pat. No. 5,936,555, conceived a “QWERTY combination keyboard and mouse system”. The invention provides for an essentially standard QWERTY keyboard that is split with about half the keys being on one keyboard part and the other half of the keys on the other keyboard part, with no keys appearing between the T and Y keys. Typically the one keyboard part which is operated by the left hand is a stationary keyboard part while the other keyboard part which is operated by the right hand is a mobile keyboard part and can also be used for the mouse function.

On this “QWERTY combination keyboard mouse system” it is important to ensure that the mobile part is not too “top heavy” which would make the part cumbersome and inaccurate to use when moved around as a mouse, and which could result in repetitive stress injuries. It is to this end that some keys (for example the Backslash and Backspace keys) on the “QWERTY” combination keyboard mouse system” have been moved from their standard positions.

A convenient position to relocate one of these keys to would be to the right of the T key on the stationary keyboard part making it is easy for the user to reach while touch typing.

It is an objective of this invention to overcome the limitation of the “QWERTY combination keyboard and mouse system” which does not provide for a key/s between the T and Y keys, by specifying at least one of the relocated keys (or any other key) to be located to the right of the T key on the left hand stationary unit, creating a QWERTxY layout, where x is any data input key.

A QWERTY keyboard is a keyboard utilizing conventional data input keys in which the top line of alphabetic keys are arranged left to right as q, w, e, r, t, y.

### SUMMARY OF INVENTION

According to the invention, there is provided a combined keyboard pointing arrangement which includes at least one moveable keyboard part moveably arranged on a support surface; and a communication means for at least one of the moveable keyboard parts for operative communication with a computer or other electronic equipment to cause movement of a pointing member.

Two moveable keyboard parts may be provided, one preferably being adapted to be operated by the left hand of a user and the other preferably being operable by the right hand of a user.

At least one data input key is located between the T and Y keys.

The arrangement may include a transducer(s) to detect relative movement or positioning of the moveable keyboard part or one of the keyboard parts relative to the support surface.

The transducer(s) may include any suitable monitoring means to monitor relative movement or position such as a rolling ball, radio frequency locating, optical locating, electrostatic sensing or pressure sensitive pad.

The moveable keyboard part(s) may be moveably supported by any suitable means, such as sliders or rollers.

The moveable keyboard part(s) may have locating recesses or ridges or surfaces for cooperation with particular fingers or palm of a user, e.g. thumb, ring finger, small finger, etc.

The moveable keyboard part(s) may have gripping or resting surface to enable any finger(s) and or palm(s) of the user's hand(s) to establish a grip on the moveable keyboard part(s) in order to move the moveable keyboard part(s) as required.

The locating recesses or ridges and/or the gripping or resting surfaces may be associated with sensors adapted to cause operation of a pointing member.

During non-operation of the pointing member, the resting surfaces may be high friction material to prevent movement of the associated keyboard part.

The communication means may include a wireless communications system, e.g. infra-red, radio frequency or optical system.

### BRIEF DESCRIPTION OF DRAWINGS

The invention will now be described by way of example with reference to the accompanying schematic drawings.

In the drawings there is shown:

FIG. 1 a plan view of a first embodiment of an integrated keyboard pointing arrangement in accordance with the invention;

FIG. 2 a sectional end view seen along arrows |—| in FIG. 1 (for clarity some details are not shown and some details are not to scale).

### DETAILED DESCRIPTION OF DRAWINGS

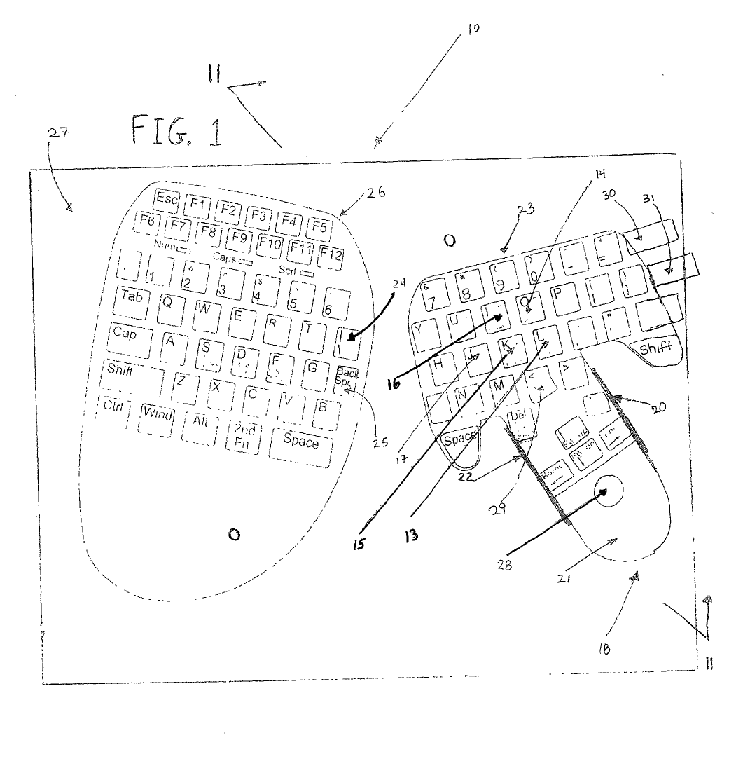

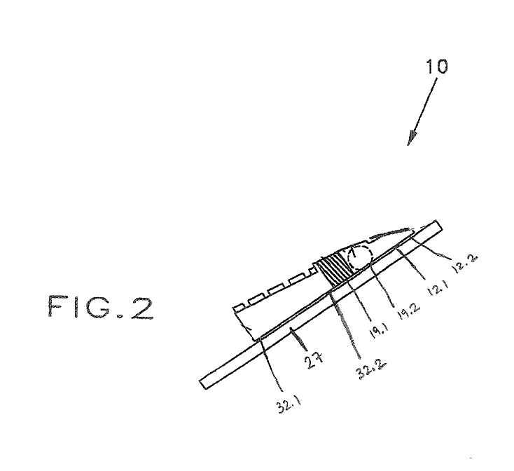

Referring to FIGS. 1 and 2, an integrated keyboard pointing arrangement 10 according to the invention is shown. The description below will describe the embodiment of the invention with one mobile keyboard part 23 and one stationary part 26, but it must be understood that both keyboard parts could be made to be mobile.

The arrangement 10 includes a stationary keyboard part 26 and a mobile keyboard part 23 mounted on a support surface 27 (the support surface may be a table or a suitable pad such as a mouse pad). Both keyboard parts are coupled to an associated computer in a conventional manner (details of these components not being shown). This may be via a cable or may be by way of wireless communication. The mobile part 23 is adapted to be operated by the right hand and the stationary part 26 is adapted to be operated by the left hand of a user.

The mobile part 23 includes suitable surfaces to allow the hand to grip the mobile part as follows: a gripping surface 22 for the thumb is provided, while a gripping surface 20 is included for either or both, the small and ring fingers. The mobile part 23 also includes a palm rest 21. The palm rest 21 may be adjustable to suit the size and shape of the band of the user. The part 22 may be fitted with a sensing device, which may be a transducer or a button. Alternatively the sensing device may be located on the small/ring finger grip 20. It may also be possible to have sensing devices on both 22 and 20. The description below assumes that the sensing device is on the part 22.

The mobile part 23 has a cut-out 18 to allow either or both the small and the ring fingers to be in contact with the support surface 27 while it/they are gripping the mobile part 23. Alternatively the small finger may rest on the support surface 27 without touching the mobile part 23.

A transducer 28 is located on the mobile part 23 to detect the relevant movement of the mobile part 23 relative to the support surface 27.

The Backslash key 24 has been moved from its normal position indicated by 31. The Backspace key 25 has been moved from its normal position indicated by 30.

The arrangement 10 operates in two main modes of operation: The first mode is the standard mode of operation, being the so-called “keyboard mode”. In this mode the arrangement 10 acts as a keyboard in the conventional manner. During pauses while typing the palm can rest on the part 21. In this mode, even if movement of part 23 occurs, the transducer 28 may be deactivated and no movement of the cursor occurs. This deactivation may be by hardware or software control.

The second mode of operation is the so-called “mouse modes” or pointing modes. In this embodiment of the invention there are three mouse modes described.

In Mouse Mode one, the hand of the user moves from the neutral typing position to the mouse mode one position by moving one key length to the right and one key length in the direction of the palm grip part 21 and then dropping onto the palm rest 21. Thus minimal movement of the hand occurs in changing from the keyboard mode to the mouse mode one and vice versa. Placing the thumb against the part 22 activates this mode. The sensing arrangement 22 senses the presence of the thumb and activates the “mouse mode”. The ring finger can grip the part 20, the small finger can rest on the support surface 27 and the palm can rest on the part 21 and may also rest partially on the support surface 27. A firm grip of the mobile part 23 by the operator is thus established. The position of the operator's hand thus aligns the pointing finger on the “<” key 29 and the middle finger on the “L” key 13. These keys act as the conventional left and right mouse click buttons when the part 23 is in the mouse mode one. The transducer 28 determines the movement of the mobile mouse pointer part 23 relative to the support surface 27. This movement causes the mouse cursor to move on the screen of the computer to which the arrangement is communicating.

In Mouse Mode two, the hand of the user may remain in the neutral typing position with placement of the thumb against the part 22 activating the mouse mode of operation. The sensing arrangement senses the presence of the thumb and activates the “mouse mode”. The small finger can grip the part 20 while the palm can rest on the palm rest 21 and may also rest partially on the support surface 27. A firm grip of the mobile part 23 by the user is thus established. The position of the operators hand thus aligns the pointing finger on the “J” key 17, the middle finger on the “K” key 15 and the ring finger on the “L” key 13 with the “J” and “L” keys being the conventional left and right mouse click buttons and the “K” key being the conventional middle mouse click button. In this configuration no sideways movement of the users hand is required to move between the typing position and the mouse position or vice versa. In this configuration transition between the keyboard mode and mouse mode is achieved by merely clenching or unclenching the hand in a natural manner. This action is instinctive and almost instantaneous.

In Mouse Mode three, the hand of the user may remain in the neutral typing position with placement of the thumb against the part 22 activating the mouse mode of operation. The sensing arrangement senses the presence of the thumb and activates the “mouse mode”. The small finger can grip the part 20 while the palm can rest on the palm rest 21 and may also rest partially on the support surface 27. A firm grip of the mobile part 23 by the user is thus established. The position of the operators hand aligns the pointing finger on the “J” key 17, the middle finger on the “I” key 16 and the ring finger on the “O” key 14 with the “J” and “O” keys being the conventional left and right mouse click buttons and the “I” key being the conventional middle mouse click button. In this configuration no sideways movement of the users hand is required to move between the typing position and the mouse position or vice versa. In this configuration transition between the keyboard mode and mouse mode is achieved by merely clenching or unclenching the hand in a natural manner. This action is instinctive and almost instantaneous.

When the thumb is removed from the sensing device 22, the keyboard mode is reactivated

19.1, 19.2, 12.1 and 12.2 are low friction sliders while 32.1 and 32.2 are high friction feet. During mouse modes the mobile keyboard part 23 is moveably supported by the low friction sliders 19.1, 19.2, 12.1 and 12.2 and is easily moved about on the support surface 27. During mouse modes the high friction feet 32.1 and 32.2 do not fully rest on the support surface 27 and do not retard the movement of the mobile keyboard part 23.

During keyboard mode when the user strikes a key on the mobile keyboard part 23, the mobile keyboard part 23 tilts forward slightly so that the high friction feet 32.1 and 32.2 rest firmly on the support surface. The resultant high friction retards the movement of the mobile keyboard part 23 on the support surface 27.

1. A combined keyboard and pointing system for use with a computer, said system comprising a keyboard comprising at least two keyboard parts having keys for generating keying commands, wherein substantially all keys of a generally QWERTY keyboard are located on said keyboard, with about half the keys being on a first keyboard part and the other half of the keys on a second keyboard part, with at least one data input key being located on either or both said keyboard parts, said data input key/s being located between the T and Y keys, the first keyboard part being adapted to be gripped by one hand of the user and be moved on a support surface as a mobile keyboard part to generate pointing movement commands to cause movement of a pointing member on said computer associated therewith, at least one transducer to detect relative movement or positioning of the mobile keyboard part relative to the support surface, and a communication means for said first and second keyboard parts to send said pointing movement commands and said keying commands to said computer.

2. The system of claim 1, wherein the second keyboard part is adapted to be gripped by a hand of the user as a mobile keyboard part, said first keyboard part being adapted to be operated by the right hand of the user and said second keyboard part being operable by the left hand of the user.

3. The data input key arrangement in claim 1, wherein said data input key between the T and the Y is the backslash or backspace data input key.

4. The data input key arrangement in claim 2, wherein said data input key between the T and the Y is the backslash or backspace data input key.

5. A combined keyboard and pointing system for use with a computer, said system comprising:
two separate and distinct keyboard parts for generating keying and pointing commands,
said first keyboard part is stationary,
said second keyboard part is mobile,
said mobile keyboard part adapted to house at least one sensing device on a gripping surface wherein an operator is capable of activating from keyboard mode to mouse mode,
a backslash data input key located between the T and Y keys based on a generally QWERTY keyboard layout,
a backspace data input key located between the G and H keys based on a generally QWERTY keyboard layout, and
a number lock data key located between the B and N keys based on a generally QWERTY keyboard layout,
said backslash data input key located on said first stationary keyboard part,
said backspace data input key located on said first stationary keyboard part,
said number lock data input key located on said second mobile keyboard part,
at least one transducer to detect relative movement or positioning of mobile keyboard part relative to a support surface, and
a communication means for said first and second keyboard parts to send said pointing movement commands and said keying commands to said computer.
